(19) United States
(12) Patent Application Publication
(10) Pub. No.: US 2010/0157662 A1
(43) Pub. Date: Jun. 24, 2010

(54) MRAM AND METHOD FOR WRITING IN MRAM

(76) Inventors: Teruo Ono, Kyoto (JP); Akinobu Yamaguchi, Osaka (JP); Saburo Nasu, Osaka (JP)

Correspondence Address: HARNESS, DICKEY & PIERCE, P.L.C., P.O. BOX 8910, RESTON, VA, 20195, US

(21) Appl. No.: 11/919,189

(22) PCT Filed: Apr. 26, 2006
(86) PCT No.: PCT/JP2006/308772

§ 371 Date: Oct. 24, 2007

(30) Foreign Application Priority Data
Apr. 26, 2005 (JP) 2005-128505

(51) Int. Cl. G11C 11/00; G11C 11/14; G11C 7/00

(52) U.S. Cl. 365/158; 365/171; 365/189.16

(57) ABSTRACT

In one embodiment of the present invention, an MRAM is an MRAM including: a plurality of write word lines; a plurality of bit lines provided so as to intersect with the write word lines; and TMR elements provided at respective intersections of the write word lines and the bit lines. Each of the TMR elements includes a first ferromagnetic layer of which magnetization direction is variable, a second ferromagnetic layer of which magnetization direction is fixed, and a tunnel wall which is sandwiched between the first ferromagnetic layer and the second ferromagnetic layer. The bit line is provided, for example, so as to bulge in the direction in which the write word line extends at the intersection of the bit line and the write word line, so that a magnetic wall is introduced at a desired position of the bit line. Further, a current fed through the bit line is fed through the first ferromagnetic layer at the time of data writing. This makes it possible to provide the MRAM having a gigabit-class capacity.

### TECHNICAL FIELD

The present invention relates to an MRAM and a method for writing in an MRAM. Particularly, the present invention relates to an MRAM having TMR elements.

### BACKGROUND ART

Magnetic Random Access Memory (MRAM) is a memory device into which data is written by changing the direction of spins (magnetization) by application of a current to a magnetic member and from which data is read by using resistance change caused by the change in direction of spins.

FIG. 7 is an explanatory view illustrating the structure of the conventional MRAM. As illustrated in FIG. 7, an MRAM 50 has a TMR (Tunneling Magnetoresistive) element 51 which performs writing and reading operations, a bit line 52, a write word line 53, a read word line 54, and an MOS transistor 58.

As illustrated in FIG. 7, the TMR element 51 has a first ferromagnetic layer 55, a second ferromagnetic layer 56, and a tunnel wall 57. The tunnel wall 57 is provided between the first ferromagnetic layer 55 and the second ferromagnetic layer 56. The first ferromagnetic layer 55 has magnetization M11 of which direction can be reversed from +X direction to −X direction and vice versa, whereas the second ferromagnetic layer 56 has magnetization M10 of which direction is fixed to one direction (+X direction).

Information is written in the MRAM 50 as illustrated in FIG. 7. That is, a current I10 is fed through the bit line 52, and a current I11 or a current I12 is fed through the write word line 53. Then, a magnetic field synthesized from (i) a magnetic field B10 generated around the bit line 52 and (ii) a magnetic field B11 or B12 generated around the write word line 53 reverses the direction of the magnetization M11 of the first ferromagnetic layer 55, so that information is written in the MRAM 50.

Specifically, the direction of the magnetization M11 of the first ferromagnetic layer 55 becomes identical with or opposite to the direction of the magnetization M10 of the second ferromagnetic layer 56, according to whether the current I11 or the current I12 is fed through the write word line 53. When the direction of the magnetization M11 is identical with that of the magnetization M10, “0” is written in the MRAM 50. On the other hand, when the direction of the magnetization M11 is opposite to that of the magnetization M10, “1” is written in the MRAM 50. This writing is performed only in the TMR element 51 which is located at a position—where the magnetic field generated around the bit line 52 intersect with the magnetic field generated around the write word line 53. In other words, the magnetization M11 of the first ferromagnetic layer 55 is not reversed if one of the magnetic field B10 of the bit line 52 or the magnetic field B11 or B12 of the write word line 53 is not present.

More specifically, information is written in the MRAM 50 as follows: That is, when a current I11 is fed through the write word line 53 in −Y direction that is a direction parallel to the write word line 53, the magnetic field B11 is generated around the write word line 53. A magnetic field synthesized from the magnetic field B11 and the magnetic field B10 which is generated by the current I10 fed through the bit line 52 turns the magnetization M11 of the first ferromagnetic layer to −X direction. This makes the direction of the magnetization M11 of the first ferromagnetic layer 55 antiparallel to the direction of the magnetization M10 of the second ferromagnetic layer 56, which makes it difficult to feed a current through the TMR element 51. As a result of this, a resistance value of the TMR element 51 increases.

On the other hand, when a current is fed through the write word line 53 in +Y direction, the magnetic field B12 is generated around the write word line 53. A magnetic field synthesized from the magnetic field B12 and the magnetic field B10 which is generated by the current I10 fed through the bit line 52 turns the magnetization M11 of the first ferromagnetic layer 55 to +X direction. This makes the direction of the magnetization M11 of the first ferromagnetic layer 55 parallel to the direction of the magnetization M10 of the second ferromagnetic layer 56, which makes it easy to feed a current through the TMR element 51. As a result of this, a resistance value of the TMR element 51 decreases.

Meanwhile, data is read from the MRAM 50 by using resistance change of the TMR element 51 caused when the MOS transistor 58 is turned on. That is, data is read by recognizing the state where the magnetization M11 of the first ferromagnetic layer 55 is in +X direction as “0” and recognizing the state where the magnetization M11 of the first ferromagnetic layer 55 is in −X direction as “1”.

However, the above MRAM structure has the following problem: Miniaturization of the TMR element 51 for an increased storage capacity sharply increases a value of a current required for the writing, i.e. the reversal of the magnetization M11 of the first ferromagnetic layer 55. Accordingly, a high current needs to be fed through the bit line 2 and the write word line 53. However, when a high current is fed through the bit line 52 and the write word line 53, there occurs the damage to the write word line 53 and the bit line 52. For this reason, MRAM capacity is limited to only about 64 Mbits to 128 Mbits.

One of the solutions for the above problem is to adopt a method called current-induced magnetization reversal in which magnetization is reversed by using the phenomenon in which a spin-polarized current fed through a TMR element applies spin torque to the magnetization. For the current-induced magnetization reversal, a critical current density required for magnetization reversal is as high as approximately 10⁷ A/cm². When such a high current is passed through a tunnel wall that constitutes the TMR element, there may occur the damage to the tunnel wall. Therefore, the current-induced magnetization reversal is not an effective method for providing a large-capacity MRAM at this time.

[Patent Document 1]

Japanese Unexamined Patent Publication No. 174149/2003 (published on Jun. 20, 2003)

[Patent Document 2]

Japanese PCT National Phase Unexamined Patent Publication No. 527123/2004 (published on Sep. 2, 2004)

[Non-Patent Document 1]

Appl. Phys. Lett. 72 (1998) 1116-111. Magnetization reversal in submicron magnetic wire studied by using giant magneto resistance effect

[Non-Patent Document 2]

J. Appl. Phys. 93 (2003) 8430-8432. Dynamics of a magnetic domain wall in magnetic wires with an artificial neck

[Non-Patent Document 3]

J. Magn. Magn. Mater. 286, (2005) 167-170. Temperature dependence of depinning fields in submicron magnetic wires with an artificial neck

[Non-Patent Document 4]

DAUGHTON J M and POHM A V. Design of Curie point written magnetoresistance random access memory cells. J. Appl. Phys. Vol. 93 No. 10, American Institute of Physics. May 15, 2003, pp. 7304-7306

### DISCLOSURE OF INVENTION

The present invention has been attained to solve the above problem, and an object thereof is to provide an MRAM having a gigabit-class capacity and to provide a method for writing data in the MRAM.

In order to achieve the object, the MRAM of the present invention is an MRAM including: a plurality of write word lines; a plurality of bit lines provided so as to intersect with the write word lines; and TMR elements provided at respective intersections of the write word lines and the bit lines, wherein: the TMR element includes a first magnetic member of which magnetization direction is variable, a second magnetic member of which magnetization direction is fixed, and an insulator which is sandwiched between the first magnetic member and the second magnetic member; the bit line is provided so that a magnetic wall is introduced at a desired position of the bit line; and a current fed through the bit line is fed through the first magnetic member at a time of data writing.

Further, in order to achieve the above object, a method for writing in an MRAM according to the present invention is a method for writing data in an MRAM including: a plurality of write word lines; a plurality of bit lines provided so as to intersect with the write word lines; and TMR elements provided at respective intersections of the write word lines and the bit lines, wherein: the TMR element includes a first magnetic member of which magnetization direction is variable, a second magnetic member of which magnetization direction is fixed, and an insulator which is sandwiched between the first magnetic member and the second magnetic member; the bit line is provided so that a magnetic wall is introduced at a desired position of the bit line; and a current fed through the bit line is fed through the first magnetic member at a time of data writing.

As described above, the TMR element needs to be miniaturized for the realization of a large-capacity MRAM. However, the miniaturization of the TMR element may cause damage to the bit line and the write word line. For this reason, MRAM capacity is limited to only about 64 Mbits to 128 Mbits.

According to the above arrangement, the bit line is provided so as to have a magnetic wall introduced at a desired position. For example, the bit line obliquely intersects with the write word line, and bulges in a direction in which the write word line extends at the intersection of the bit line and the write word line. Additionally, as described previously, the TMR element is provided at the intersection of the bit line and the write word line. In other words, the bit line is bulged in a direction in which the write word line extends at the position where the TMR element is provided.

Therefore, in the initialization state (state where the magnetic field is 0) before a current is fed through the write word line, the magnetization on the bit line which obliquely intersects with the write word line is aligned in a direction parallel to the bit line. Additionally, the bit line is bulged in the direction in which the write word line extends, at the intersection of the bit line and the write word line. Because of this, a magnetic wall is formed in the first magnetic member at the position where the bulge is present (the desired position). That is, a boundary is formed between the areas where the magnetization directions are opposite.

Since the current fed through the bit line is also fed through the first magnetic member, the magnetic wall is pushed by the current. Then, when a current fed through the write word line generates a magnetic field around the write word line, the magnetic wall moves and the magnetization direction of the first magnetic member is changed.

As a result of diligent research, the inventors of the present invention confirmed that the use of magnetic wall movement enables “0” or “1” to be written in the MRAM with no need to feed a high current to the bit line and the write word line. Therefore, a low current is fed through the write word line and the word line at the time of information writing. This makes it possible to miniaturize the TMR element and thus increase MRAM capacity up to gigabit-class capacity, without damage to the write word line and the word line.

In other words, the bit line is provided so as to obliquely cross the write word line and symmetric to the write word line.

The inventions disclosed in Patent Documents 1 and 2 have the same object as the present invention, i.e. decrease of the amount of operating power and the amount of current at the time of writing. However, the Patent Documents 1 and 2 do not disclose the technical idea that the bit line is bulged in the direction in which the write word line extends at the intersection of the bit lien and the write word line. Thus, the inventions disclosed in Patent Documents 1 and are totally different from the present invention.

### BRIEF DESCRIPTION OF DRAWINGS

FIG. 1 is a plan view illustrating the structure of an intersection of a bit line and a write word line in an MRAM according to the present embodiment.

FIG. 2 is an oblique perspective view illustrating the structure of the MRAM illustrated in FIG. 1.

FIG. 3(a) is a view illustrating the state where an external magnetic field is applied to the MRAM illustrated in FIG. 1.

FIG. 3(b) is a view illustrating the state where an angle which the magnetization direction of a second ferromagnetic layer forms with a direction in which the write word line extends is an acute angle.

FIG. 4 is an oblique perspective view illustrating the state where constrictions are provided to the bit line of the MRAM illustrated in FIG. 2.

FIG. 5 is a plan view illustrating the state where folds are provided to the bit line illustrated in FIG. 1.

FIG. 6 is a graph showing that the MRAM of the present embodiment decreases the amount of current passing through the bit line.

FIG. 7 is an oblique perspective view illustrating the structure of the conventional MRAM.

### BEST MODE FOR CARRYING OUT THE INVENTION

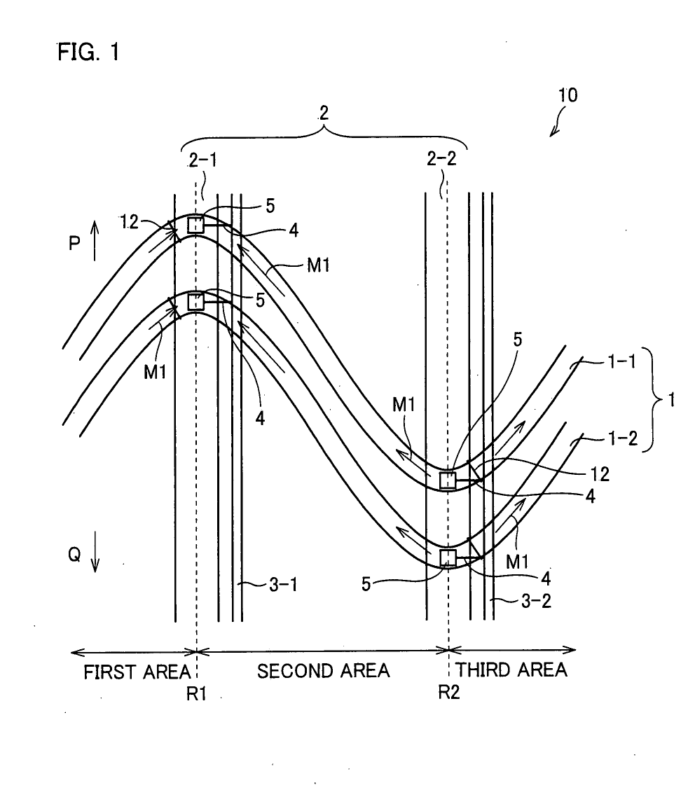

The following will describe an embodiment of the present invention with reference to drawings. FIG. 1 is a plan view of an MRAM (Magnetic Random Access Memory) of the present embodiment. As illustrated in FIG. 1, an MRAM 10 includes a plurality of bit lines 1-1, 1-2 . . . which are provided in a curve forming the letter S (curved lines), a plurality of write word lines 2-1, 2-2, . . . which are provided parallel to one another, and read word lines 3-1, 3-2, . . . .

In FIG. 1, only two bit lines and two write word lines are illustrated. However, as a matter of course, bit lines and write word lines are provided in an actual MRAM in such a manner that the number of bit lines and the number of write word lines correspond to the size of the storage capacity of the MRAM. In the following descriptions, the bit lines 1-1, 1-2, . . . are simply referred to as “bit lines 1”, the write word lines 2-1, 2-2, . . . are simply referred to as “write word lines 2”, and read word lines 3-1, 3-2, . . . are simply referred to as “read word lines 3”.

At each intersection of the bit line 1 and the write word line 2, an MOS transistor 4 and a TMR element 5 are provided. The read word line 3 is provided near the write word line 2 and parallel to the write word line 2. Furthermore, the read word line 3 is connected to the TMR element 5 via the transistor 4.

Now, the locations of the bit line 1 and the write word line 2 are described specifically. As illustrated in FIG. 1, the bit line 1 is provided so as to obliquely cross the write word line 2-1 and the write word line 2-2. In other words, the bit line 1 is provided so as not to be orthogonal to the write word line 2 and so as not to be parallel to the write word line 2.

More specifically, the bit line 1 is bulged in a P direction or in a Q direction at the position where the bit line 1 passes through the write word line 2 (at the position where the bit line 1 straddles the write word line 2; at the position where the bit line 1 intersects with the write word line 2). The P direction is a direction in which the write word line 2 extends, and the Q direction is opposite to the P direction. At the intersection of the bit line 1 and the write word line 2-1, the bit line 1 is bulged in the P direction. On the other hand, at the intersection of the bit line 1 and the write word line 2-2, the bit line 1 is bulged in the 0 direction. However, this arrangement is only an example, and the direction in which the bit line 1 is bulged may be either the P direction or the Q direction.

The bit lines 1 are axially symmetric about axes R1 and R2 that extend in a longitudinal direction of the write word line 2. In the present embodiment, the bit line 1 is realized by a ferromagnetic layer.

The following describes the locations of the bit line 1 and the write word line 2 more specifically. For example, the bit line 1 is provided in such a manner that the write word line 2 forms an acute angle, e.g. 45 degrees with a line that passes through (i) a center point of a section where the bit line 1 is orthogonal to the write word line 2-1 and (ii) a center point of a section where the bit line 1 is orthogonal to the write word line 2-2.

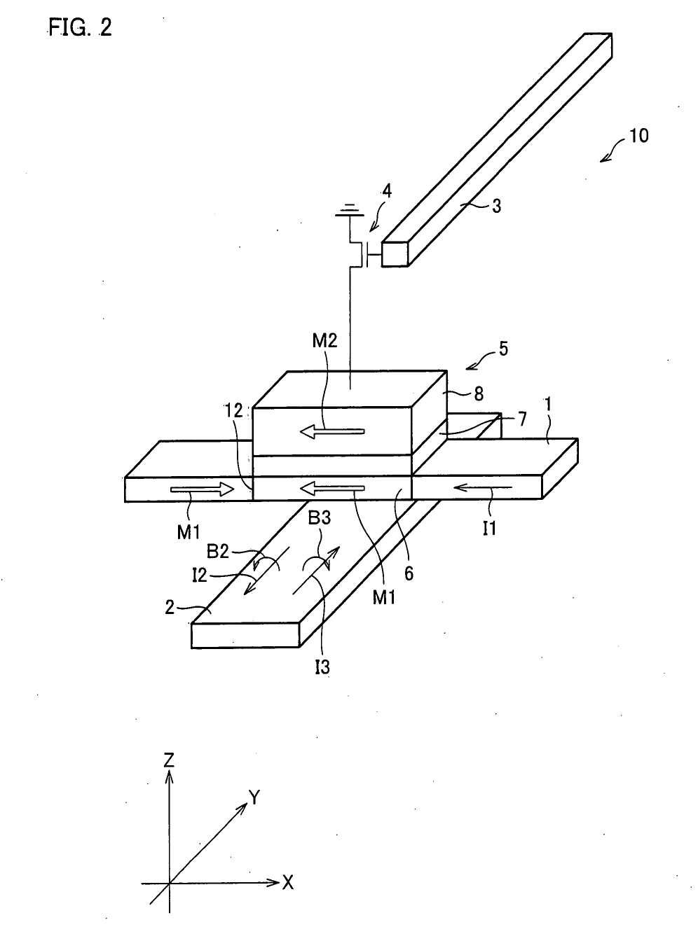

FIG. 2 is an oblique perspective view illustrating the structure of the intersection of the bit line 1 and the write word line 2 and its surroundings in the MRAM 10. At this intersection, the TMR element 5′ is provided. The TMR element 5 includes: a first ferromagnetic layer (also termed a write layer and a free layer) 6 made from a metal (alloy primarily comprised of iron, e.g. FeCo alloy); a tunnel wall (also termed tunnel barrier) 7; and a second ferromagnetic layer (also termed a fixed layer) 8 made from a metal (alloy primarily comprised of iron, e.g. FeCo alloy). The tunnel wall 7 has a thickness of several nanometers, and composed of aluminum oxide, magnesium oxide, or the like, for example.

Furthermore, the bit line 1 has a boundary (magnetic wall) 12 on which the magnetization direction of the bit line 1 is opposite to the direction of magnetization M1 of the first ferromagnetic layer 6, as will be detailed later. Movement of the magnetic wall 12 allows the MRAM 10 to change the direction of the magnetization M1 of the first ferromagnetic layer 6. That is, it is possible to write data in the MRAM 10.

The second ferromagnetic layer 8 is arranged such that the direction of magnetization M2 therein is fixed to +X direction. The direction of the magnetization M2 in the second ferromagnetic layer 8 can be fixed by, for example, an antiferromagnetic layer (not shown). However, the one that fixes the direction of magnetization is not limited to the antiferromagnetic layer and can be anything if it is capable of fixing the direction of magnetization.

By arranging the bit line 1 as illustrated in FIG. 1, the magnetization M1 of the bit line 1 can be aligned as below in an initialization state (detailed later) before information is written in the MRAM 10, i.e. before currents are fed through the bit line 1 and the write word line 2.

Note that “initialization state” is the so-called initialization state in which the intensity of a magnetic field is zero. The following will describe the procedure of initialization.

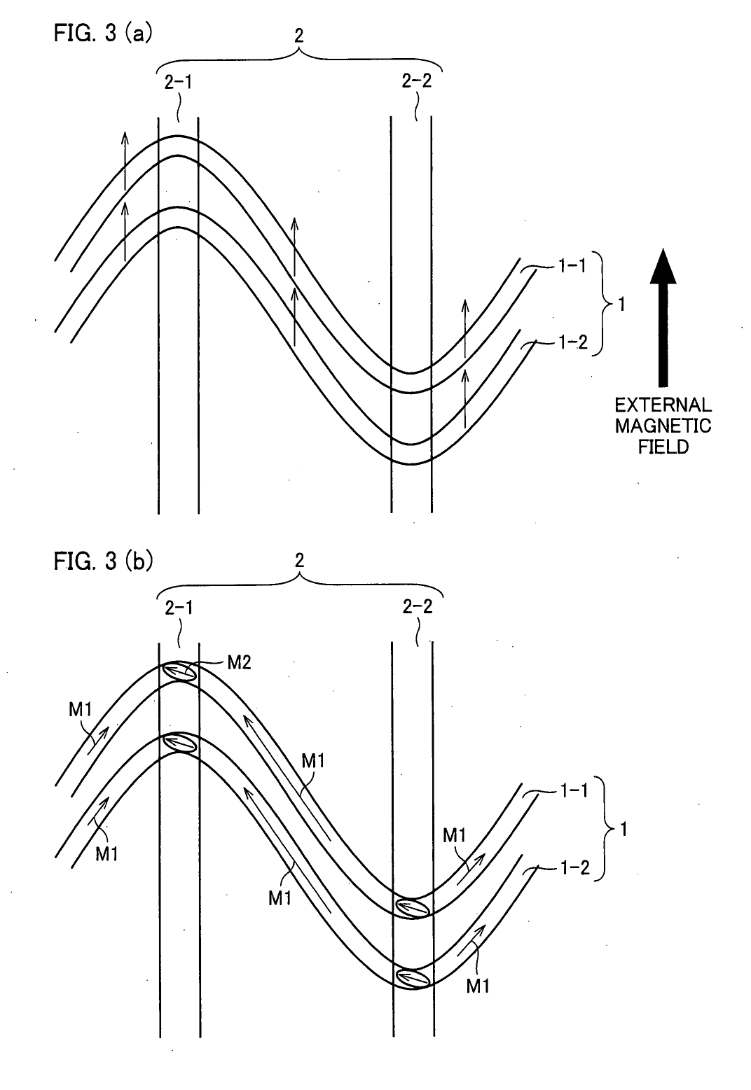

As illustrated in FIG. 3(a), a sufficiently high external magnetic filed is applied to the write word line 2 by using an electromagnet or the like so as to be parallel to the write word line 2. This aligns the magnetization of the bit line 1 in a direction in which the write word line 2 extends.

Then, when the external magnetic field is removed, the magnetization M1 of the bit line 1 is aligned toward an axis R1 in a first area illustrated in FIG. 1, i.e. an area that is located on the side of the axis R1 opposite the axis R2 by shape magnetic anisotropy. The axis R1 is a line passing through the center of the write word line 2-1, whereas the axis R2 is a line passing though the center of the write word line 2-2.

In a second area illustrated in FIG. 1, i.e. an area between the axis R1 and the axis R2, the magnetization M1 of the bit line 1 is aligned toward the axis R1 from the axis R2. In other words, the magnetization M1 of the bit line 1 in the first area reverses along the bit line 1. This forms a boundary between the areas whose directions of the magnetization M1 are opposite to each other, near the axis R1 in the bit line 1 (near the position at which the TMR element 5 is provided). The boundary between the areas whose directions of the magnetization are opposite to each other is referred to as a magnetic wall, which is given reference numeral 12 in FIG. 1.

In a third area illustrated in FIG. 1, i.e. an area that is located on the side of the axis R2 opposite the axis R1, the magnetization of the bit line 1 is aligned away from the axis R2. In other words, the magnetization M1 of the bit line 1 in the third area reverses along the bit line 1. This forms a boundary between the areas whose magnetization directions are opposite to each other near the axis R2. The boundary between the areas whose magnetization directions are opposite to each other is also referred to as a magnetic wall, which is given reference numeral 12 in FIG. 1.

Application of a high external magnetic field may change the magnetization direction of the second ferromagnetic layer 8. In order to prevent the magnetization direction of the second ferromagnetic layer 8 from varying before and after the application of the external magnetic field, an angle which the magnetization direction of the second ferromagnetic layer 8 forms with the direction in which the write word line 2 extends should be an acute angle, as illustrated in FIG. 3(b). This makes it possible to prevent the magnetization direction of the second ferromagnetic layer 8 from varying before and after the application of the external magnetic field.

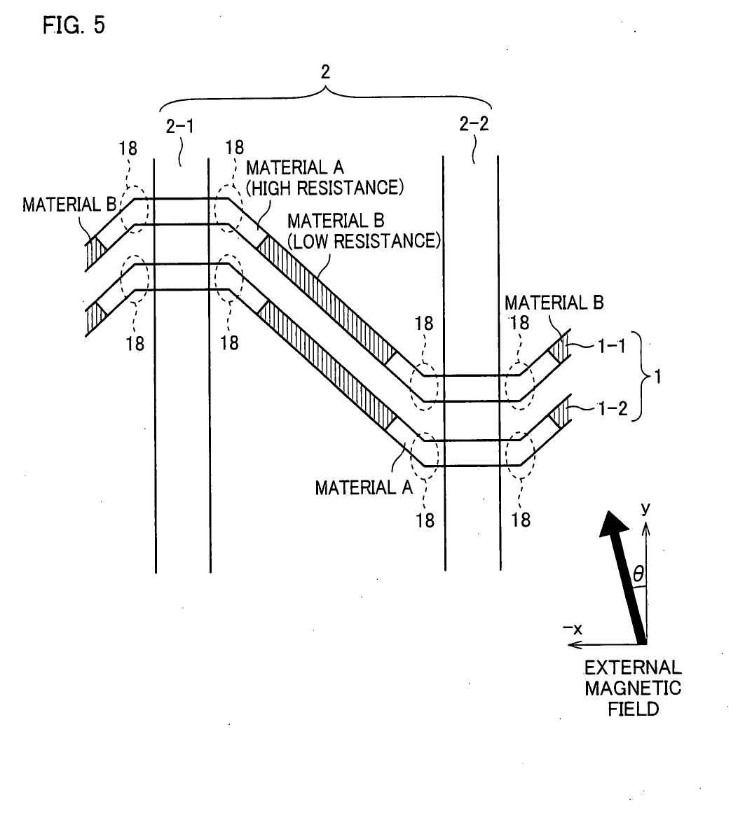

Incidentally, the MRAM 10 performs data writing by moving the magnetic wall, as will be detailed later. Because of this, the MRAM 10 requires a magnetic wall to be introduced at a preferred position (desired position) in the vicinity of the intersection of the bit line 1 and the write word line 2. Now, assume that the initialization is carried out with the arrangement in which the bit line 1 is provided as illustrated in FIG. 5. In this case, a magnetic wall is introduced at a folded section 18 where the bit line 1 is folded. The folded section 18 is located at a position corresponding to the desired position.

In other words, in the arrangement illustrated in FIG. 5, the bit line 1 is provided in such a manner that the folded section 18 is located at the desired position. Thus, it can be said that the bit line 1 is provided in such a manner that the magnetic wall is introduced at the desired position and that the introduced magnetic wall can be confined.

Note that the bit line 1 illustrated in FIG. 1 is provided similarly. In this case, the magnetic wall is introduced at a section where the bit line 1 is orthogonal to the external magnetic field. In other words, in the arrangement illustrated in FIG. 1, the bit line 1 is provided in such a manner that the section where the bit line 1 is orthogonal to the external magnetic filed is located at the desired position.

As described previously, in a case where the bit line 1 is folded, the magnetic wall is introduced at the folded section. That is, the magnetic wall is introduced as long as the bit line is folded. Therefore, it is needless to say that the arrangement of the folded section 18 illustrated in FIG. 5 is only an example. For example, the folded section 18 may be folded at a larger angle.

Furthermore, as described previously, in a case where the bit line 1 is provided as illustrated in FIG. 1, the external magnetic field for the initialization is applied parallel to the write word line 2. On the contrary, in a case where the bit line 1 is provided as illustrated in FIG. 5, the external magnetic field is applied at an angle θ in +y direction of a line segment y parallel to the write word line 2 and in −x direction of a line segment x vertical to the line y, as illustrated in FIG. 5. In other words, the external magnetic field for the initialization should be applied at an angle that enables introduction of a magnetic wall at the desired position of the bit line 1 provided as described previously. However, it should be noted that the angle θ must be an acute angle.

[Process of Information Writing]

Next, the following will describe the process in which information is written in the MRAM 10.

First, a current is fed through the bit line 1 corresponding to the TMR element 5 into which information is to be written. Then, the current fed through the bit line 1 generates joule heat, which causes the first ferromagnetic layer 6 of the TMR element 5 to be heated.

Here, the direction of a current I1 fed through the bit line 1 differs depending upon whether information “0” or “1” is written in the MRAM 10.

For example, assume that “0” is written in the MRAM 10. In this case, the direction (−X direction) of the magnetization M2 of the second ferromagnetic layer 8 needs to be parallel to the direction of the magnetization M1 of the first ferromagnetic layer 6. In other words, the direction of the magnetization M1 of the first ferromagnetic layer 6 needs to be −X direction. As a matter of course, the direction of the magnetization M2 of the second ferromagnetic layer 8 is only an example and may be +X direction.

Thus, in order to align the magnetization M1 of the first ferromagnetic layer 6 in −X direction, a current in +X direction should be fed through the bit line 1. Additionally, in order to select the TMR element 5 into which information is to be written, a current I2 in −Y direction (one of directions in which the write word line 2 extends) is fed through the write word line 2. This generates a magnetic field B2 around the write word line 2.

Then, the following three elements: (i) the joule heat applied to the first ferromagnetic layer 6; (ii) the current I1 that pushes the magnetic wall 12; and (iii) the magnetic field B2 generated around the write word line 2 move the magnetic wall 12 in −X direction and cause the magnetization M1 of the first ferromagnetic layer 6 to be aligned in −X direction. This makes the direction of the magnetization M1 of the first ferromagnetic layer 6 to be parallel to the direction of the magnetization M2 of the second ferromagnetic layer 8, thus enabling “0” to be written in the MRAM 10.

Meanwhile, assume that “1” is written. In this case, the direction of the magnetization M2 of the second ferromagnetic layer 8 needs to be antiparallel to the direction of the magnetization M1 of the first ferromagnetic layer 6. In other words, the direction of the magnetization M1 of the first ferromagnetic layer 6 needs to be +X direction.

Thus, in order to align the magnetization M1 of the first ferromagnetic layer 6 in +X direction, a current i1 in −X direction should be fed through the bit line 1. Additionally, in order to select the TMR element 5 into which information is to be written, a current I3 in +Y direction is fed through the write word line 2. This generates a magnetic field B3 around the write word line 2.

Then, the following three elements: (i) the joule heat applied to the first ferromagnetic layer 6; (ii) the current I1 that pushes the magnetic wall 12; and (iii) the magnetic field B3 generated around the write word line 2 move the magnetic wall 12 in +X direction and cause the magnetization M1 of the first ferromagnetic layer 6 to be aligned in +X direction. This makes the direction of the magnetization M1 of the first ferromagnetic layer 6 to be antiparallel to the direction of the magnetization M2 of the second ferromagnetic layer 8, thus enabling “1” to be written in the MRAM 10.

Here, the principle of the movement of the magnetic wall 12 by the current I1 will be described below.

First, the magnetic wall 12 changes its magnetization direction little by little. When the current I1 is fed through such a magnetic wall 12, carriers carrying electrical charges (also having spins) are scattered by the magnetic wall 12, the momentum of scattering is applied to the magnetization. As a result of this, the magnetic wall 12 moves in a direction in which carriers flow (momentum transfer effect).

When the carriers pass through the magnetic wall 12, the direction of spins is reversed from the magnetization direction before the carriers pass through the magnetic wall to the magnetization direction after the carriers pass through the magnetic wall 12. Change of spin angular momentum caused by the spin reversal of the carriers is applied to the magnetic wall 12. As a result of this, the magnetic wall 12 moves in a direction that meets conservation law of angular momentum in the entire system (spin transfer effect).

In this manner, the current I1 fed in +X direction can move the magnetic wall 12 in −X direction, and the magnetization M1 of the first ferromagnetic layer 6 can be aligned in −X direction. In addition, the current I1 fed in −X direction moves the magnetic wall 12 in +X direction, and the magnetization M1 of the first ferromagnetic layer 6 can be aligned in +X direction.

In the above descriptions, the following three elements: (i) the joule heat applied to the first ferromagnetic layer 6; (ii) the current I1 that pushes the magnetic wall 12; and (iii) the magnetic field B2(B3) generated around the write word line 2 move the magnetic wall 12. However, the balance between the three elements may be adjusted as appropriate. In other words, a value of the current I1 is decreased and the intensity of the magnetic field B2(B3) generated around the write word line 2 is increased correspondingly. Furthermore, the three elements may be adjusted in the following manner, for example. That is, a value of one of the three elements is set to 0, and values of the other two elements are set to be values that offset the decrease in the one of the three elements.

The above-described relationship between the direction of the current I1 and the direction in which the magnetic wall moves is only an example. That is, the direction of the current I1 and the direction in which the magnetic wall moves can be identical with each other, depending upon what material is used for the first ferromagnetic layer 6.

The above descriptions assume that the bit line 1 and the first ferromagnetic layer 6 are made from the same material. However, the compositions of the bit line 1 and the first ferromagnetic layer 6 are not limited to this.

For example, as illustrated in FIG. 5, a portion of the bit line 1 may be replaced by the first ferromagnetic layer 6. That is, the bit line 1 (made from material B in FIG. 5) may be cut in front of the multilevel intersection of the bit line 1 and the write word line 2 so that the first ferromagnetic layer 6 (portion made from material A in FIG. 5) is provided in such a manner that cut ends of the bit line 1 are joined via the first ferromagnetic layer 6. In other words, a portion of the bit line 1 at the intersection of the bit line 1 and the write word line 2 is replaced by the first ferromagnetic layer 6. In still other words, the first ferromagnetic layer 6 may be integral with the bit line 1 so that a current is fed through the bit line 1.

Further, as illustrated in FIG. 5, portions of the bit line 1 other than the first ferromagnetic layer 6 may be made from a material being of a low resistance and less likely to generate heat (material B in FIG. 5). The resistance of the bit line 1 may be decreased by increasing a cross sectional area of the bit line 1 in the portions other than the first ferromagnetic layer 6. The decrease of a resistance value of the bit line 1 in this manner causes the first ferromagnetic layer 6 to efficiently generate heat even when a voltage applied to the bit line 1 is decreased. This makes it possible to change the direction of magnetization of the first ferromagnetic layer 6 at a lower current, thus allowing for energy savings.

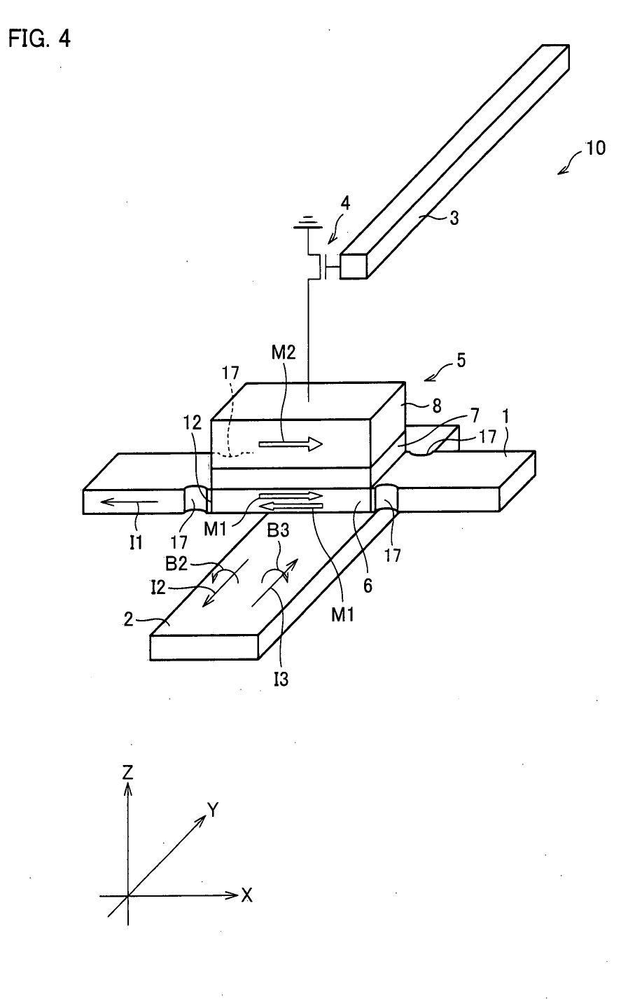

Still further, as illustrated in FIG. 4, the bit line 1 may have constrictions 17 on its side surfaces. The constrictions 17 are preferably provided around the intersection of the bit line 1 and the write word line 2. Provision of the constrictions 17 allows the position at which the magnetic wall 12 stops (position where the magnetic wall 12 is introduced) to be a preferred position around the intersection of the bit line 1 and the write word line 2 (see Non-patent Documents 1 through 3).

Yet further, as illustrated in FIG. 5, the bit line 1 may be arranged so as to be folded at the intersection of the bit line 1 and the write word line 2 and to have the folded sections 18. Provision of the folded sections 18 allows the position at which the magnetic wall 12 stops to be a preferred position around the intersection of the bit line 1 and the write word line 2.

The locations of the bit line 1 and the write word line 2 illustrated in FIG. 5 are described more specifically. The bit line 1 is provided in such a manner that the bit line 1 connecting (i) the folded section 18 provided near the write word line 2-1 and (ii) the folded section 18 provided near the write word line 2-2 extends so as to straddle the write word line 2-1, for example, and the extended bit line 1 forms an acute angle, e.g. 45 degrees with the write word line 2-1.

Finally, the following will describe advantageous effects brought by the MRAM of the present embodiment employing magnetic wall movement, unlike the MRAM employing current-induced magnetization reversal (hereafter referred to as spin injection MRAM).

The spin injection MRAM reverses magnetization of a magnetic member with a single magnetic domain by spin injection. Both in writing information and in reading information, a current is fed through the TMR element. In other words, a common circuit is used both at the time of writing information and at the time of reading information.

The MRAM is arranged such that information is written with a low current for the reduction of power consumption, whereas information is read with a high current for the realization of a sufficient voltage drop. This gives rise to the problem that information is erroneously written at the time of reading information.

In the case of the current-induced magnetization reversal, a critical current density required for magnetization reversal is as high as approximately 10⁷ A/cm². When such a high current is fed, there may occur the damage to the tunnel wall that constitutes the TMR element.

On the contrary, in the case of the MRAM of the present embodiment, a current is fed through the TMR element only at the time of reading information (at the time of writing information, a current for pushing the magnetic wall is fed though the bit line 1, as described previously). In other words, a circuit used at the time of writing information is different from a circuit used at the time of reading information. Therefore, erroneous writing at the time of reading does not occur. In addition, since a low current is fed through the tunnel wall that constitutes the TMR element, the damage to the tunnel wall does not occur.

[Operation and Effect]

The MRAM 10 of the present embodiment is such that the bit line 1 is bulged in the direction in which the write word line 2 extends, at the position where the bit line 1 passes through the write word line 2. This forms the magnetic wall 12 in the bit line 1. The magnetic wall 12 can be moved according to the direction of a current fed through the bit line 1.

As a result of diligent research, the inventors of the present invention found that employing the movement of the magnetic wall 12 enables writing of “0” or “1” in the MRAM 10 without a necessity to feed a high current through the bit line 1 and the write word line 2.

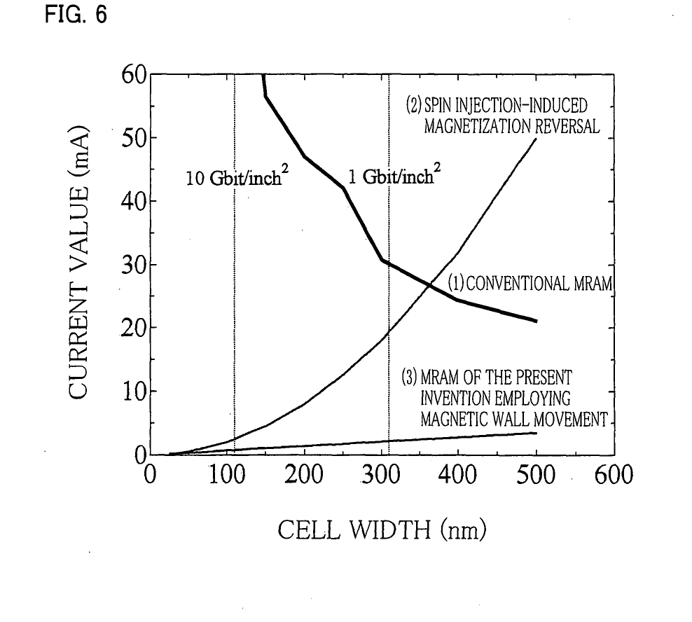

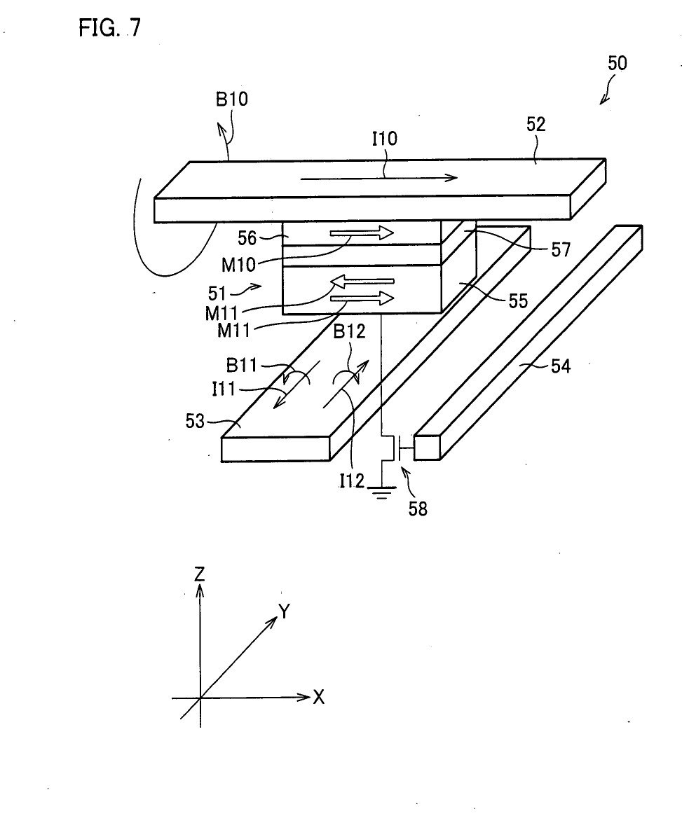

For reference, FIG. 6 shows the result of the comparison between a current fed through the bit line in the MRAM 10 of the present embodiment (line (3) in the graph of FIG. 6), a current fed in the conventional MRAM that performs magnetization reversal (line (1) in the graph of FIG. 6), and a current fed in the MRAM that performs current-induced magnetization reversal (line (2) in the graph of FIG. 6). As is clear from FIG. 6, the MRA of the present embodiment employing magnetic wall movement realizes a significant decrease of the amount of current fed through a bit line.

Therefore, it is possible to prevent damage to the bit line 1 and the write word line 2 even when the TMR element 5 is miniaturized. This makes it possible to increase MRAM capacity up to a gigabit-class capacity.

Further, the provision of the first ferromagnetic layer 6 in replacement of a portion of the bit line 1, the use of the bit line 1 that is made from a material having a low electrical resistance, such as copper, and the use of the first ferromagnetic layer 6 that is made from a material having a high electrical resistance (Ni₈₁Feₗ₉ or the like) enable the first ferromagnetic layer 6 to efficiently generate heat even when a voltage applied to the bit line 1 is decreased. It has been recently reported that the first ferromagnetic layer 6 realized by FeCoB alloy brings a significant TMR effect.

Then, when the first ferromagnetic layer 6 is heated, the direction of magnetization of the first ferromagnetic layer 6 easily changes (see Non-patent Document 4). This enables writing of “0” or “1” in the MRAM 10 only by feeding a low current through the bit line 1 and the write word line 2, thus allowing for energy savings at the time of writing information in the MRAM.

The MRAM of the present embodiment may be arranged such that the first magnetic member is provided in replacement of a portion of the bit line. Further, the MRAM of the present embodiment may be arranged such that the first magnetic member is provided integral with the bit line so that a current is fed through the bit line. Still further, the MRAM of the present embodiment may be arranged such that the bit line is cut in front of the intersection of the bit line and the write word line, and the first magnetic member is provided between cut ends of the bit line so that the cut ends are joined via the first magnetic member.

Yet further, the MRAM of the present embodiment may be arranged such that the bit line has an electrical resistance lower than that of the first magnetic member.

According to the above arrangement, an electrical resistance of the bit line is lower than that of the first magnetic member. This increases the amount of heat generated by the first magnetic member, thus easily changing the magnetization direction of the first magnetic member. Furthermore, this enables the first magnetic member to efficiently generate heat even when a voltage applied to the bit line is decreased, thus allowing for energy savings.

Further, the MRAM of the present embodiment may be arranged such that the bit line is made from a material having an electrical resistance lower than that of the first magnetic member. Still further, the MRAM of the present embodiment may be arranged such that the bit line is made from a material that is identical with a material from which the first magnetic member is made. Yet further, it is preferable that the bit line has a cross-sectional area larger than that of the first magnetic member.

### INDUSTRIAL APPLICABILITY

The present invention can be preferably applied to memory provided in a personal computer, a mobile telephone, and the like.

1. (canceled)

2. An MRAM comprising:
a plurality of write word lines;
a plurality of bit lines provided so as to intersect with the write word lines; and
TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and the bit line is provided so as to have a bulged portion which is provided at the intersection of the bit line and the write word line and bulges in a direction in which the write word line extends; and
a current fed through the bit line is fed through the first magnetic member at a time of data writing.

3. An MRAM comprising:
a plurality of write word lines;
a plurality of bit lines provided so as to intersect with the write word lines; and
TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and the bit line is provided so as to have a fold at the intersection of the bit line and the write word line; and
a current fed through the bit line is fed through the first magnetic member at a time of data writing.

4. An MRAM comprising:
a plurality of write word lines;
a plurality of bit lines provided so as to intersect with the write word lines; and
TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line;
the first magnetic member is provided in replacement of a portion of the bit line; and
a current fed through the bit line is fed through the first magnetic member at a time of data writing.

5. An MRAM comprising:
a plurality of write word lines;
a plurality of bit lines provided so as to intersect with the write word lines; and
TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and the bit line is integral with the first magnetic member;
at a time of data writing, currents are fed through the bit line and the write word line, and the current fed through the bit line is fed through the first magnetic member; and
data is written by using (a) movement of the introduced magnetic wall by the current fed through the first magnetic member, (b) a magnetic field which is formed by the current fed through the write word line, and (c) heat generation of the first magnetic member caused by the current fed through the first magnetic member.

6. An MRAM comprising:
a plurality of write word lines;
a plurality of bit lines provided so as to intersect with the write word lines; and
TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and the bit line is cut in front of the intersection of the bit line and the write word line;
the first magnetic member is provided between cut ends of the bit line so that the cut ends are joined via the first magnetic member; and
a current fed through the bit line is fed through the first magnetic member at a time of data writing.

7. The MRAM according to claim 2, wherein
the bit line has an electrical resistance lower than that of the first magnetic member.

8. The MRAM according to claim 2, wherein
the bit line is made from a material having an electrical resistance lower than that of the first magnetic member.

9. An MRAM comprising:
a plurality of write word lines;
a plurality of bit lines provided so as to intersect with the write word lines; and
TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is made from a material that is identical with a material from which the first magnetic member is made, and the bit line is provided so that a magnetic wall is introduced at a desired position of the bit line; and
a current fed through the bit line is fed through the first magnetic member at a time of data writing.

10. The MRAM according to claim 9, wherein
the bit line has a cross-sectional area larger than that of the first magnetic member for realization of energy savings at the time of data writing.

11. An MRAM comprising:
a plurality of write word lines;
a plurality of bit lines provided so as to intersect with the write word lines; and
TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and the bit line is provided so as to obliquely cross the write word line and so as to be symmetric to the write word line; and
a current fed through the bit line is fed through the first magnetic member at a time of data writing.

12. An MRAM comprising:
a plurality of write word lines;
a plurality of bit lines provided so as to intersect with the write word lines; and
TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and the bit line is bent in a curve at the intersection of the bit line and the write word line; and
a current fed through the bit line is fed through the first magnetic member at a time of data writing.

13. An MRAM comprising:
a plurality of write word lines;
a plurality of bit lines provided so as to intersect with the write word lines; and
TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and a portion of the bit line at the intersection of the bit line and the write word line is replaced by the first magnetic member; and
a current fed through the bit line is fed through the first magnetic member at a time of data writing.

14. (canceled)

15. A method for writing data in an MRAM including: a plurality of write word lines; a plurality of bit lines provided so as to intersect with the write word lines; and TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and the bit line is provided so as to have a bulged portion which is provided at the intersection of the bit line and the write word line and bulges in a direction in which the write word line extends; and
a current fed through the bit line is fed through the first magnetic member at a time of data writing.

16. A method for writing data in an MRAM including: a plurality of write word lines; a plurality of bit lines provided so as to intersect with the write word lines; and TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and the bit line is provided so as to have a fold at the intersection of the bit line and the write word line; and
a current fed through the bit line is fed through the first magnetic member at a time of data writing.

17. A method for writing data in an MRAM including: a plurality of write word lines; a plurality of bit lines provided so as to intersect with the write word lines; and TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and the bit line is bent in a curve at the intersection of the bit line and the write word line; and
a current fed through the bit line is fed through the first magnetic member at a time of data writing.

18. A method for writing data in an MRAM including: a plurality of write word lines; a plurality of bit lines provided so as to intersect with the write word lines; and TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and a portion of the bit line at the intersection of the bit line and the write word line is replaced by the first magnetic member; and
a current fed through the bit line is fed through the first magnetic member at a time of data writing.

19. A method for writing data in an MRAM including: a plurality of write word lines; a plurality of bit lines provided so as to intersect with the write word lines; and TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and the bit line is provided so as to obliquely cross the write word line and so as to be symmetric to the write word line; and
a current fed through the bit line is fed through the first magnetic member at a time of data writing.

20. A method for writing data in an MRAM including: a plurality of write word lines; a plurality of bit lines provided so as to intersect with the write word lines; and TMR elements provided at respective intersections of the write word lines and the bit lines, wherein:
the TMR element includes a first magnetic member of which magnetization direction is variable, a second magnetic member of which magnetization direction is fixed, and an insulator which is sandwiched between the first magnetic member and the second magnetic member;
the bit line is provided so that a magnetic wall is introduced at a desired position of the bit line, and the bit line is integral with the first magnetic member;
at a time of data writing, currents are fed through the bit line and the write word line, and the current fed through the bit line is fed through the first magnetic member; and
data is written by using (a) movement of the introduced magnetic wall by the current fed through the first magnetic member, (b) a magnetic field which is formed by the current fed through the write word line, and (c) heat generation of the first magnetic member caused by the current fed through the first magnetic member.
